(19) United States
(12) Patent Application Publication
(10) Pub. No.: US 2025/0069892 A1
(43) Pub. Date: Feb. 27, 2025

(54) PLANARIZATION METHOD AND METHOD OF MANUFACTURING ARTICLE

(71) Applicant: CANON KABUSHIKI KAISHA, Tokyo (JP)

(72) Inventor: KENJI YAEGASHI, Tochigi (JP)

(21) Appl. No.: 18/802,472

(22) Filed: Aug. 13, 2024

(30) Foreign Application Priority Data
Aug. 21, 2023 (JP) 2023-134156

(51) Int. Cl. H01L 21/3105; G03F 7/00; H01L 21/02; H01L 21/67

(52) U.S. Cl. CPC H01L 21/31051; H01L 21/02282; H01L 21/02345; H01L 21/67253; G03F 7/0002; H01L 21/67092

(57) ABSTRACT

A planarization method of repeatedly performing a planarization process a plurality of times on the same surface of a substrate is provided. The superstrate is provided with a tapered surface connecting a side end face to a flat surface forming a lower surface facing the substrate. In a second planarization process after a first planarization process, a curable material is supplied so as to cover a region of a cured film formed under the tapered surface in the first planarization process with a liquid film formed in the second planarization process.

### BACKGROUND OF THE INVENTION

### Field of the Invention

The present invention relates to a planarization method and a method of manufacturing an article.

### Description of the Related Art

As the need for miniaturizing semiconductor devices increases, not only a conventional photolithography technique but also a microfabrication technique for molding an uncured curable material on a substrate using a mold and curing it to form a pattern of the curable material on the substrate has received a great deal of attention. This technique is called an imprint technique, and can form a fine pattern on a several nanometer order on a substrate.

One of the imprint techniques is, for example, a photo-curing method. An imprint apparatus that employs the photo-curing method molds, using a mold, a photo-curable material supplied to a shot region on a substrate, cures the curable material by light irradiation, and separates the mold from the cured material, thereby forming a pattern on the substrate.

Recently proposed is a technique of planarizing a curable material on a substrate (see Japanese Patent Laid-Open No. 2011-529626). The technique disclosed in Japanese Paten Laid-Open No. 2011-529626 is designed to improve planarization accuracy by dropping a curable material based on the stepped surface of a substrate and curing the curable material while keeping a planar surface of a mold in contact with the dropped curable material.

The main items concerning planarization performance include planarity, film thickness, and defect. These items may pose problems particularly at an outer peripheral portion of a planarized film. For example, if the application amount of a curable material is small or the application area is narrow, a mold may come into contact with a substrate without through the curable material to cause particles or defects or affect the durability of the mold or the substrate. Such contact between a mold and a substrate without through a curable material is called dry contact. In contrast to this, if, for example, the application amount of a curable material is large or the application area is wide, the curable material exudes from between the mold and the substrate. This exudation may spread around to the reverse surface of the substrate to contaminate the apparatus, may result in a case where the cured curable material adheres to the mold at the time of mold separation to affect the planarization performance in a subsequent planarization process, or may become a cause of a defect occurring upon dropping of the cured curable material.

Measures to prevent such problems at an outer peripheral portion of a planarized film include a method that provides the outer periphery of a flat portion of a mold with a tapered portion (see Japanese Patent Laid-Open Nos. 2020-004877 and 2021-160352). Providing the outer periphery of the flat portion of the mold with the tapered portion can suppress an increase in the radial spread amount of a curable material with an increase in the film thickness of the curable material at the tapered portion even if the curable material exudes from between the flat portion of the mold and the substrate. In contrast to this, a shortage of curable material will cause dry contact. Accordingly, when a mold provided with a tapered portion is to be used, a curable material is supplied such that the material exudes from between the flat portion of the mold and a substrate.

In planarizing a substrate using a planarization apparatus, a desired planarity cannot sometimes be obtained by one planarization process depending on the density or unevenness of a device pattern. In such a case, executing a planarization process a plurality of times can reduce the unevenness of the surface and improve the planarity. If the mold provided with the tapered portion described above is used, the outer peripheral portion of the planarized film has a bulging portion formed by the tapered portion. This bulging portion exists within the non-critical range of accuracy allowed in a general semiconductor process and is removed in a subsequent step, thus posing no problem. When, however, a planarization process is performed for the same substrate a plurality of times, a bulging portion generated by a previous planarization process interferes with the mold in the second and subsequent planarization processes. Since the bulging portion generated in the previous planarization process has already been cured, this interference is also dry contact like contact between the mold and the substrate without through the curable material described above. Such dry contact may cause particles or defects or affect the durability of the mold or the substrate.

### SUMMARY OF THE INVENTION

The present disclosure provides a technique advantageous in preventing dry contact in a planarization process.

The present invention in its one aspect provides a planarization method of repeatedly performing a planarization process a plurality of times on the same surface of a substrate, the planarization process including supplying a curable material onto a substrate, forming a liquid film on the substrate by bringing a superstrate into contact with the curable material supplied onto the substrate, forming a cured film by curing the liquid film, and separating the superstrate from the cured film, wherein the superstrate is provided with a tapered surface connecting a side end face to a flat surface forming a lower surface facing the substrate, and in the supplying the curable material in a second planarization process after a first planarization process, the curable material is supplied so as to cover a region of the cured film formed under the tapered surface in the first planarization process with a liquid film formed in the forming the liquid film in the second planarization process.

Further features of the present invention will become apparent from the following description of exemplary embodiments (with reference to the attached drawings).

### BRIEF DESCRIPTION OF THE DRAWINGS

FIG. 1 is a view showing the arrangement of a planarization apparatus;

FIGS. 2A to 2C are views for explaining an outline of a planarization process;

FIG. 3 is a flowchart showing a planarization process according to an embodiment;

FIGS. 4A to 4F are views for explaining dry contact occurring in a plurality of planarization processes according to the embodiment;

FIGS. 5A to 5D are views showing the states of a mold, a substrate, and a curable material in a planarization process;

FIG. 6 is a view showing the state of a curable material at a spread end;

FIGS. 7A to 7G are views for explaining a plurality of planarization processes that cause no dry contact according to the embodiment;

FIGS. 8A to 8D are views showing the states of a mold, a substrate, and a curable material in a planarization process; and

FIGS. 9A to 9C are views exemplarily showing how dry contact is prevented.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

### First Embodiment

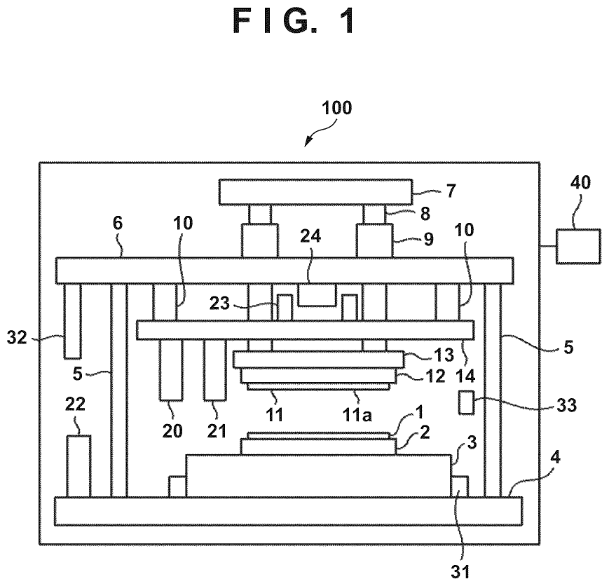

FIG. 1 is a schematic view showing the arrangement of a planarization apparatus 100 according to an embodiment. The planarization apparatus 100 is embodied by a forming apparatus that molds a curable material on a substrate 1 by using a mold 11. In this embodiment, the planarization apparatus 100 planarizes a curable material on a substrate. The planarization apparatus 100 forms a global or local flat surface of a curable material on a substrate by curing the curable material while keeping the curable material on the substrate in contact with a mold and separating the mold from the cured curable material.

A silicon wafer is a typical example of the base material of the substrate 1. However, the invention is not limited to this. The substrate 1 can be formed of a material arbitrarily selected from materials known as substrate materials for semiconductor devices, such as aluminum, a titanium-tungsten alloy, an aluminum-silicon alloy, an aluminum-copper-silicon alloy, silicon oxide, and silicon nitride. Note that a substrate on which an adhesion layer has been formed by surface treatment such as silane coupling treatment, silazane treatment, film formation of an organic thin film, or the like to improve the adhesiveness to the curable material may be used as the substrate 1. Note that the substrate 1 typically has a circular shape with a diameter of 300 mm, but is not limited thereto.

As the mold 11, a mold formed of a light transmissive material is preferably used in consideration of the light irradiation step. Specifically, as a material for the mold, it is preferable to use glass, quartz, polymethyl methacrylate (PMMA), a phototransparent resin such as a polycarbonate resin, a transparent metal vapor deposition film, a flexible film such as polydimethylsiloxane, a photo-curable film, a metal film, or the like. Note that the mold 11 preferably has a circular shape with a diameter larger than 300 mm and smaller than 500 mm, but is not limited thereto. Preferably, the diameter of the mold 11 can be 200 mm to 400 mm. The thickness of the mold 11 is preferably 0.25 mm or more and less than 2 mm, but is not limited thereto.

In the case of an imprint apparatus, a pattern such as a circuit pattern is formed on a mold. However, the mold 11 used in this planarization apparatus is not provided with such pattern. The mold 11 is a mold having a flat surface to be used. A mold having a flat surface used by the planarization apparatus is called a superstrate. Alternatively, such a mold is called a pressing member, a planar plate, or the like.

As a curable material, a UV curable liquid is preferably used in consideration of a light irradiation step. Typically, a monomer such as acrylate or methacrylate may be used.

In an EUV photolithography step, along with an increase of the NA, the depth of focus (to be referred to as “DOF” hereinafter) at which the projection image of a fine circuit pattern is formed is decreasing in recent years. In a recent example, the allowable DOF of an EUV lithography apparatus with NA=0.33 is 300 nm to 110 nm (depending on the illumination mode). The allowable DOF of an EUV lithography apparatus with NA=0.55 is 160 nm to 40 nm (depending on the illumination mode). However, it has been found that it is difficult for the method of applying a SOC film by a conventional spin coater to achieve the sufficient surface planarization performance which falls within the allowable range as described above. Particularly, in a case of spin coating, a layer having a uniform film thickness is formed on a wafer due to the viscosity of the SOC coating agent dropped onto the substrate (wafer) and the centrifugal force by spinning. Therefore, if a region where a change in wiring density of the underlying pattern of the process wafer is 5 μm or more exists in a long cycle, the border where the wiring density changes is left intact and appears on the surface of the SOC film.

In recent years, a planarization method with an imprint technique applied thereto has been examined. In this method, a superstrate as a member with no pattern formed thereon is pressed against a composition (curable material) in a liquid state supplied onto a wafer, the composition is cured by exposure after the composition has spread, and then the superstrate is separated. Note that the term “imprint” is often used in the concept of transferring a pattern drawn on a mold by pressing the pattern, but in the planarization process, no pattern is drawn on the superstrate.

As shown in FIG. 1, the planarization apparatus 100 includes a substrate chuck 2, a substrate stage 3, a platen 4, pillars 5, a top plate 6, a guide bar plate 7, guide bars 8, a mold driver 9, pillars 10, a mold chuck 12, a head 13, an alignment rack 14. In addition, the planarization apparatus 100 includes a droplet supplier 20, an off-axis alignment (OA) scope 21, a substrate conveyer 22, an alignment scope 23, a light source 24, a stage driver 31, a mold conveyer 32, a cleaner 33, and a controller 40. The substrate chuck 2 and the substrate stage 3 constitute a substrate holder that holds the substrate 1. The mold chuck 12 and the head 13 constitute a mold holder that holds the mold 11. In this case, an XYZ coordinate system is defined such that the horizontal plane is the XY plane, and the vertical direction is the Z-axis direction.

The substrate conveyer 22 including a conveyance hand loads the substrate 1 from outside the planarization apparatus 100, for example, from a container containing substrates. The substrate chuck 2 holds the substrate 1. The substrate stage 3 is held by the platen 4 and driven in the X-axis direction and the Y-axis direction to position the substrate 1 held by the substrate chuck 2 at a predetermined position. The stage driver 31 includes a linear motor and an air cylinder and drives (moves) the substrate stage 3 in at least the X-axis direction and the Y-axis direction. However, the stage driver 31 may have a function of driving the substrate stage 3 in directions more than two axis directions (for example, six axis directions). In addition, the stage driver 31 includes a rotation mechanism and rotationally drives (rotates) the substrate chuck 2 or the substrate stage 3 around an axis parallel to the Z-axis direction.

The mold conveyer 32 including a conveyance hand loads the mold 11 from outside the planarization apparatus 100, for example, a container containing molds. The mold chuck 12 holds the mold chuck 12. The mold 11 has, for example, a circular or rectangular outer shape and includes a planar portion 11a as a lower surface. The planar portion 11a has such rigidity as to conform to the surface shape of the substrate 1 upon coming into contact with the curable material on the substrate. The planar portion 11a has a size equal to or larger than that of the substrate 1. The mold chuck 12 is supported by the head 13 and has a function of correcting rotation or the like of the mold 11 around the Z-axis. The mold chuck 12 and the head 13 each have an opening that transmits light (ultraviolet light) applied from the light source 24 through a collimator lens. The mold chuck 12 or the head 13 is provided with a load cell for measuring the pressing force (impressing force) of the mold 11 against the curable material on the substrate.

The platen 4 is provided with the pillars 5 that support the top plate 6. The guide bars 8 extend through the top plate 6. One end of each guide bar 8 is fixed to the guide bar plate 7, and the other end is fixed to the head 13. The mold driver 9 is a mechanism that drives the head 13 in the Z-axis direction through the guide bars 8, brings the mold 11 held on the mold chuck 12 into contact with the curable material on the substrate, and separates the mold 11 from the curable material on the substrate. The mold driver 9 has a function of driving (moving) the head 13 in the X-axis direction and the Y-axis direction and a function of rotationally driving the mold chuck 12 or the head 13 around an axis parallel to the Z-axis direction.

The alignment rack 14 is suspended on the top plate 6 through pillars 10. The guide bars 8 extend through the alignment rack 14. The alignment rack 14 is provided with a height measurement system (not shown) for measuring the height (planarity) of the substrate 1 held by the chuck 2 by using, for example, an oblique incident image shift scheme.

The OA scope 21 is supported on the alignment rack 14. The OA scope 21 detects alignment marks provided in a plurality of partial regions of the substrate 1 and is used for an alignment process of deciding the positions of the respective partial regions. The alignment scope 23 includes an optical system and an image capturing system which are used to observe the reference marks provided on the substrate stage 3 and the alignment marks provided on the mold 11. When, however, the mold 11 is provided with no alignment mark, the alignment scope 23 is not required. The alignment scope 23 measures the relative positions between the reference marks provided on the substrate stage 3 and the alignment marks provided on the mold 11 and is used for alignment for correcting positional shifts. Relative alignment between the mold 11 and the substrate 1 can be performed by obtaining the positional relationship between the mold 11 and the substrate stage 3 using the alignment scope 23 and obtaining the positional relationship between the substrate stage 3 and the substrate 1 using the OA scope 21.

The droplet supplier 20 is configured of a dispenser including a discharge orifice (nozzle) that discharges an uncured (liquid) curable material to the substrate 1, and drops and arranges (supplies) droplets of the curable material on the substrate. The droplet supplier 20 uses, for example, a piezoelectric jet system or micro-solenoid system and can supply minute-volume droplets of the curable material onto a substrate. The number of discharge orifices of the droplet supplier 20 is not specifically limited and may be one (a single nozzle) or exceed 100. That is, a linear nozzle array or a combination of a plurality of linear nozzle arrays may be used.

The cleaner 33 cleans the mold 11 while the mold 11 is held by the mold chuck 12. The cleaner 33 removes the curable material adhering to the mold 11, particularly the planar portion 11a by separating the mold 11 from the cured curable material on the substrate. The cleaner 33 may wipe out the curable material adhering to the mold 11 or remove the curable material adhering to the mold 11 by UV irradiation, wet washing, plasma cleaning, or the like.

The controller 40 includes a CPU or another processor, a processing unit such as an FPGA, and a storage unit such as a memory and controls the overall planarization apparatus 100. The controller 40 functions as a processing unit that performs a planarization process by comprehensively controlling each unit of the planarization apparatus 100.

In this case, a planarization process is a process of planarizing the curable material on a substrate by bringing the planar portion 11a of the mold 11 into contact with the curable material so as to make the planar portion 11a conform to the surface shape of the substrate 1. Note that a planarization process is generally performed for each lot, that is, each of a plurality of substrates included in the same lot.

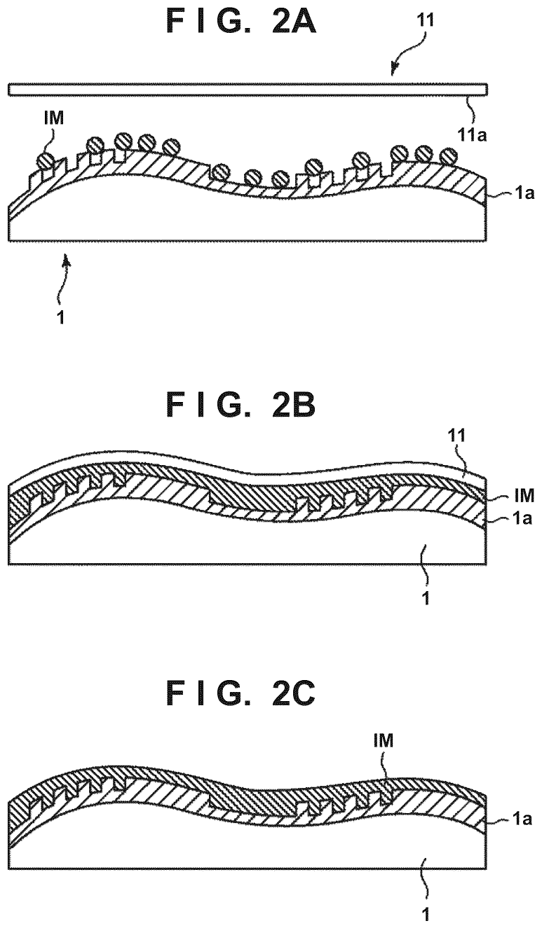

An outline of a planarization process will be described next with reference to FIGS. 2A to 2C. This embodiment will exemplify a planarization process of planarizing a curable material IM on the entire surface of the substrate 1 by bringing the curable material IM into contact with the mold 11. However, the curable material IM may be planarized by bringing the curable material on a partial region of the substrate into contact with the mold.

As shown in FIG. 2A, the droplet supplier 20 drops a plurality of droplets of the curable material IM onto the substrate 1 on which an underlying pattern is formed (a supply step). FIG. 2A shows a state before the curable material IM is supplied onto the substrate and the mold 11 is brought into contact with the curable material IM. As shown in FIG. 2B, a liquid film is formed on the substrate by bringing the curable material IM on the substrate into contact with the planar portion 11a of the mold 11 (a contact step). FIG. 2B shows a state in which the planar portion 11a of the mold 11 entirely comes into contact with the curable material IM on the substrate and conforms to the surface shape of the substrate 1. In the state shown in FIG. 2B, the light source 24 irradiates the curable material IM on the substrate with light to cure the curable material IM via the mold 11, thereby forming a cured film (a curing step). As shown in FIG. 2C, the mold 11 is separated from the curable material on the substrate (a separation step). This makes it possible to form a planarized layer of the curable material IM with a uniform thickness on the entire surface of the substrate 1. FIG. 2C shows a state in which the planarized layer of the curable material IM is formed on the substrate.

In performing such planarization process, an excess or shortage of the curable material IM to be applied can cause problems such as defects caused by dry contact or exudation between the mold 11 and the substrate 1. In this embodiment, in order to solve this problem, the outer periphery of the flat portion of the mold 11 is provided with a tapered portion. That is, the mold 11 is provided with a tapered surface that connects a side end face to the flat surface forming the lower surface facing the substrate 1. The controller 40 controls the amount of exudation of the curable material IM from between the flat portion of the mold 11 and the substrate 1. Even if the curable material IM exudes from between the flat surface of the mold 11 and the substrate 1, the film thickness of the curable material IM increases under the tapered surface to suppress the radial spread amount. This makes it possible to prevent the curable material IM from adhering to an end portion of the mold 11 and an end portion of the substrate 1.

However, a desired planarity cannot sometimes be obtained by one planarization process depending on the density or unevenness of a device pattern. In such a case, executing a planarization process on the same surface a plurality of times can reduce the unevenness of the surface and improve the planarity. If the mold 11 provided with the tapered portion described above is used, the outer peripheral portion of the planarized film has a bulging portion formed by the tapered portion. This bulging portion exists within the non-critical range of accuracy allowed in a general semiconductor process and is removed in a subsequent step, thus posing no problem. When, however, a planarization process is performed for the same substrate a plurality of times, a bulging portion generated by the previous planarization process interferes with the mold 11 in the second and subsequent planarization processes. Since the bulging portion generated in the previous planarization process has already been cured, this interference is also dry contact like contact between the mold 11 and the substrate 1 without through the curable material described above. Such dry contact may cause particles or defects or affect the durability of the mold 11 or the substrate 1.

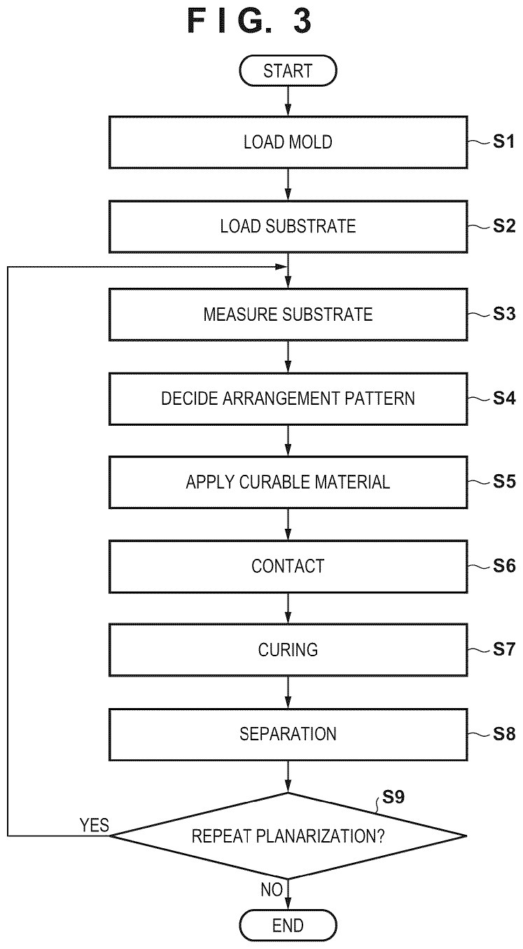

Accordingly, in this embodiment, in a supply step in the second planarization process after the first planarization process, a curable material is supplied so as to cover the region of a cured film formed under the tapered surface in the first planarization process with the liquid film formed in a contact step in the second planarization process. For example, with respect to the spread region of the curable material IM formed in the previous planarization process (first planarization process), the application range of the curable material IM in the next planarization process (second planarization process) is set to be larger than that in the previous planarization process. That is, the supply range of the curable material in the supply step in the second planarization process is set to be larger than the cured film formed in the first planarization process. This makes it possible to prevent dry contact by covering the entire surface of the film formed in the previous planarization process with the curable material IM. A planarization process in this embodiment will be described in detail with reference to FIGS. 3, 4A to 4F, and 5A to 5D.

FIG. 3 is a flowchart showing an example of a planarization process in this embodiment.

In step S1, the controller 40 controls the mold conveyer 32 to load the mold 11 into the apparatus and mount the mold 11 on the mold chuck 12. This causes the mold chuck 12 to hold the mold 11. In step S2, the controller 40 controls the substrate conveyer 22 to load the substrate 1 into the apparatus and mount the substrate 1 on the substrate chuck 2. This causes the substrate chuck 2 to hold the substrate 1.

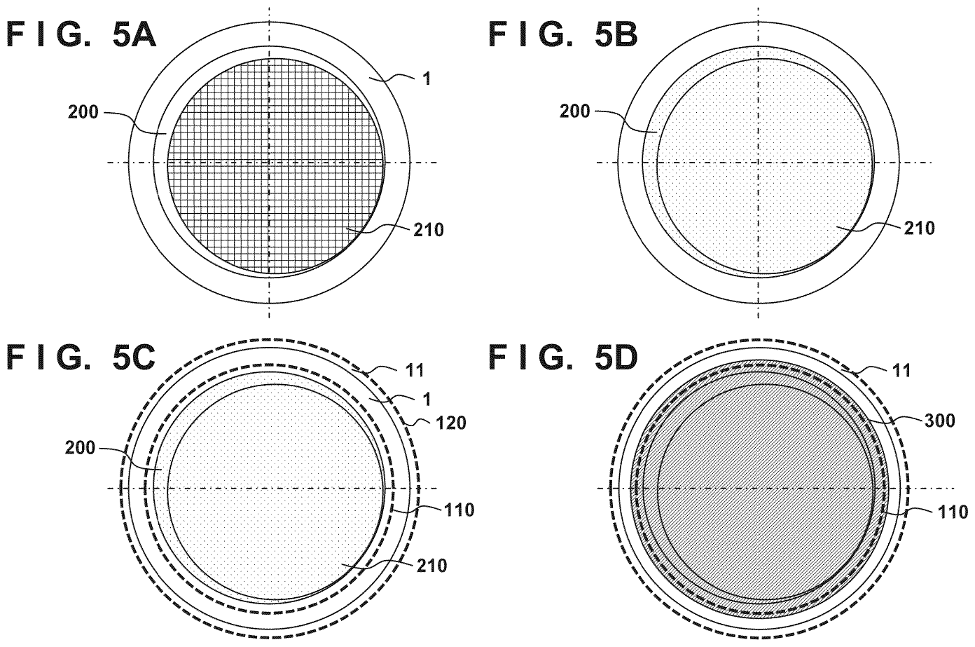

In step S3, the controller 40 executes measurement of the substrate 1 to decide the arrangement position of the curable material IM on the substrate 1. The measurement of the substrate 1 can include measurement of the boundary position or outer shape dimensions of the flat surface of the substrate 1 and measurement of a curved surface portion extending from the flat surface to the end face. The measurement of the substrate 1 can also include measurement of at least one of an alignment mark and a characteristic pattern as the position of a device pattern provided on the substrate 1. Grasping the positional relationship between the shape and the pattern of the substrate 1 can decide the arrangement position of the curable material IM relative to the substrate. For example, as shown in FIG. 5A, consider a state in which the center of a device pattern 210 represented by a lattice pattern is decentered relative to the center of the outer shape of the substrate 1. In this case, dropping the curable material IM so as to cover only the device pattern 210 and performing contact control so as to match the center of the mold 11 with that of the substrate 1 will spread the curable material IM so as to shift from the center of the mold 11 and the substrate 1. Consequently, dry contact can occur in a region with a small amount of the curable material IM or the curable material IM can exude from between the mold 11 and the substrate 1 and adhere to an end portion of the substrate 1 or the mold 11 due to a factor such as a large application amount of the curable material IM or a large application area.

In order to prevent this, in step S4, the controller 40 decides a droplet arrangement pattern free from dry contact and exudation based on the result of the measurement of the substrate 1 in step S3. More specifically, the controller 40 decides a droplet arrangement pattern so as to cover the device pattern 210 indicated by the dot pattern in FIG. 5B and an accuracy guarantee range 200 in anticipation of the spread amount of the curable material IM upon contact with the mold 11.

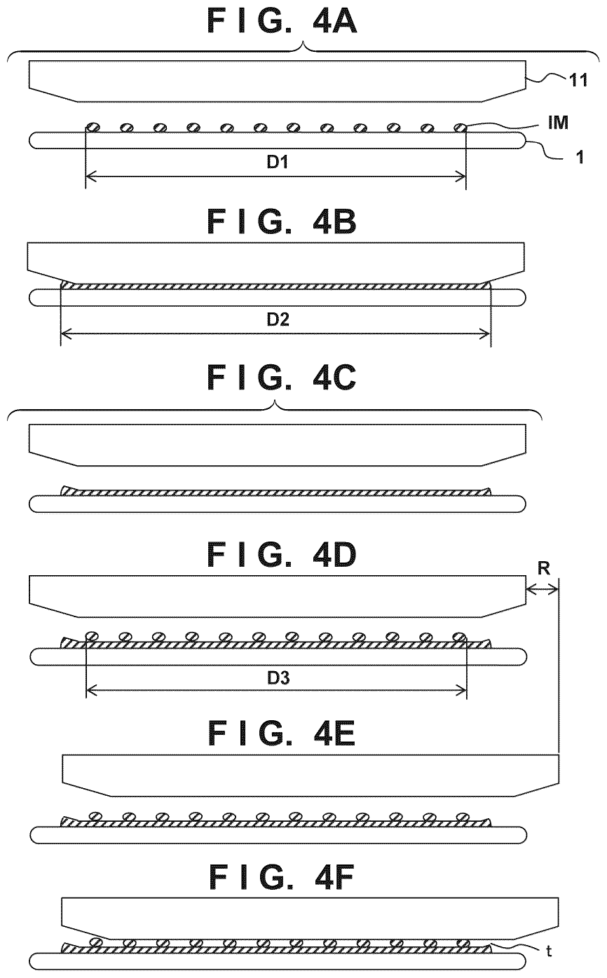

In step S5, the controller 40 applies (supplies) the curable material IM onto the substrate 1 in accordance with the decided droplet arrangement pattern. FIG. 4A shows a state in which the curable material IM is supplied onto the substrate 1 in this manner.

The controller 40 or an external computer (information processing apparatus) may create data of a droplet arrangement pattern for dropping the curable material IM onto the substrate 1. When the external computer is to create data of a droplet arrangement pattern, the controller 40 obtains the data of the droplet arrangement pattern from the external computer. Assume in the following description that the controller 40 creates a droplet arrangement pattern. The controller 40 creates, in a region D1 of the substrate 1 shown in FIG. 4A, data of a first droplet arrangement pattern for dropping the curable material with the droplet supplier 20. The first droplet arrangement pattern can be decided based on the density (roughness), pitch, width, and the like of the pattern in the region and the final thickness of a planarized layer upon planarization of the curable material IM by the mold 11.

In step S6, as shown in FIG. 5C, the controller 40 brings the mold 11 into contact with the curable material IM upon matching the center of the substrate 1 with that of the mold 11. FIG. 4B shows a state in which the mold 11 is in contact with the curable material IM. FIG. 5C shows an example in which the diameter of the mold 11 is larger than that of the substrate 1, and hence an end face 120 of the mold 11 is farther from the center than an end face of the substrate 1. However, the diameters of the mold 11 and the substrate 1 may be equal to each other or inverse to each other in terms of magnitude relationship.

When the mold 11 comes into contact with the curable material IM, the curable material IM spreads up to a spread end 300 that is an end portion of the spread region represented by the hatched pattern in FIG. 5D. At this time, the spread end 300 spreads outward from a taper start portion 110 of the mold 11. In addition, as shown in FIG. 4B, a spread region D2 as a region of the spread curable material is larger than the application range D1.

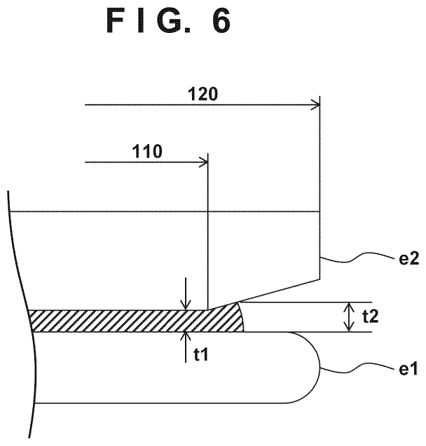

FIG. 6 shows how the curable material IM spreads outward from the taper start portion 110 of the mold 11. Providing the outer periphery of the flat surface of the mold 11 with a tapered portion will convert the radial spread of the curable material IM exuding from between the flat surface of the mold 11 and the substrate 1 in a direction of increasing thickness from a film thickness t1 to a film thickness t2. This facilitates the suppression of the spreading of the radial curable material IM and can prevent the curable material IM from adhering to an end face e1 of the substrate 1 and an end face e2 of the mold 11.

In step S7, the controller 40 cures the curable material IM by using the light source 24. Alternatively, if the curable material IM is a heat-curable material, the curable material IM is cured by heating. Thereafter, in step S8, the controller 40 controls the head 13 to separate the mold. FIG. 4C shows a state after mold separation.

As described above, in planarizing a substrate by using the planarization apparatus, a desired planarity cannot sometimes be obtained by one planarization process depending on the density or unevenness of a device pattern. In such a case, executing a planarization process a plurality of times can reduce the unevenness of the surface and improve the planarity. In step S9, the controller 40 determines whether to repeat planarization. The simplest example is that a number N of times by which planarization should be repeated is set in advance. In this case, in step S9, the controller 40 determines whether the current number of repetitions has reached N. Alternatively, the planarity of the surface of the substrate 1 may be measured, and the controller 40 may determine whether the planarity obtained by measurement falls within an allowable range. If it is determined in step S9 that planarization is to be repeated, the process returns to step S3. If it is determined in step S9 that planarization need not be repeated, the processing is terminated.

The following is a description of a case where step S3 and the subsequent steps will be executed again. In step S3, the controller 40 executes measurement of the substrate 1 to decide the arrangement position of the curable material IM on the substrate 1. Subsequently, in step S4, the controller 40 decides a droplet arrangement pattern based on the result of the measurement of the substrate 1 in step S3. In step S5, the controller 40 applies (supplies) the curable material IM onto the substrate 1 based on the decided droplet arrangement pattern. In this case, as shown in FIG. 4D, the application region of the substrate 1 is a region D3. Assume that the region D3 has the same size as that of the application range D1. In this case, the region D3 is smaller than the spread region D2 shown in FIG. 4C. Subsequently, the controller 40 performs positioning of the substrate 1 and the mold 11 based on the result of the measurement of the substrate 1 in step S3. However, the result of the positioning of the substrate 1 and the mold 11 may not perfectly match that obtained by the previous positioning due to a factor such as a measurement control error, and a positioning error R can occur as shown in FIG. 4E. In step S6, while the positioning error R occurs, the curable material IM comes into contact with the mold 11. FIG. 4F shows a state where such contact has occurred. At this time, a bulging portion t of the curable material IM of the outer peripheral tapered portion formed in the previous planarization process may come into dry contact with the mold 11. This indicates that the bulging portion t interferes with the mold 11 before the curable material IM spreads in the radial direction due to contact.

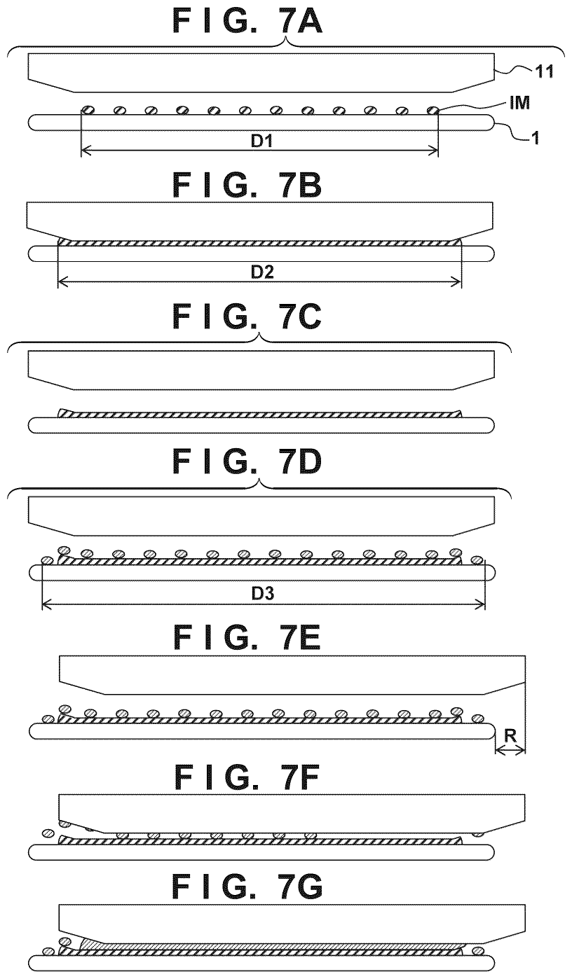

An example of this countermeasure will be described with reference to FIGS. 7A to 7G. FIGS. 7A to 7G are views for explaining a plurality of planarization processes free from dry contact according to this embodiment. In this case, FIGS. 7A to 7C show a first planarization process and are the same as in FIGS. 4A to 4C.

In a state in which steps S1 to S8, which are the first planarization process, have been executed, and the operation shown in FIGS. 7A to 7C has been completed, a planarization process is executed again through step S9. In performing the planarization process again, the controller executes measurement of the substrate 1 in step S3 to decide the arrangement position of the curable material IM on the substrate 1. This measurement of the substrate 1 includes measurement of the boundary position or outer shape dimensions of the flat surface of the substrate 1 and measurement of a curved surface portion extending from the flat surface to the end face. Alternatively, the controller may measure the spread region D2 of the curable material IM which is formed by the previous planarization process. That is, the second planarization process can include a step of measuring the outer peripheral end of the cured film formed in the first planarization process.

In step S4, the controller 40 decides a droplet arrangement pattern based on the result of the measurement of the substrate 1 in step S3. That is, the second planarization process can include a step of deciding the supply range and supply amount of the curable material in a supply step in the second planarization process based on the outer peripheral end measured in step S3. The external computer or the controller 40 may perform this step. In addition, the information of the spread region D2 of the curable material IM formed by the previous planarization process may be obtained as the result of the measurement in step S3 as described above or obtained by other experiments and analyses.

The controller 40 executes positioning of the substrate 1 and the mold 11 based on the result of the measurement of the substrate in step S3. In this positioning, the center of the substrate 1 may be matched with the center of the mold 11 or the center of the spread region D2 of the curable material IM formed by the previous planarization process may be matched with the center of the mold 11.

In step S5 in this embodiment, as shown in FIG. 7D, the curable material IM is applied to a region equal to or larger than the spread region D2 formed in the previous planarization process in the radial direction. That is, the curable material IM is applied to the region so as to cover the bulging portion. In another embodiment, the curable material IM may be applied to a region located inward from the spread region D2 formed in the previous planarization process as long as the curable material IM spreads so as to cover the bulging portion at the time of contact. That is, the supply range of the curable material in the supply step in the second planarization process may be located inward from the outer peripheral end of the cured film formed in the first planarization process. In this case, however, in the contact step in the second planarization process, the curable material is spread such that the liquid film extends over the outer peripheral end of the cured film. For example, the supply range of the curable material in the supply step in the second planarization process can be defined to be −0.5 mm larger than the outer peripheral end of the cured film formed in the first planarization process. In this manner, the curable material IM is applied so as to prevent the mold 11 from coming into dry contact with the bulging portion.

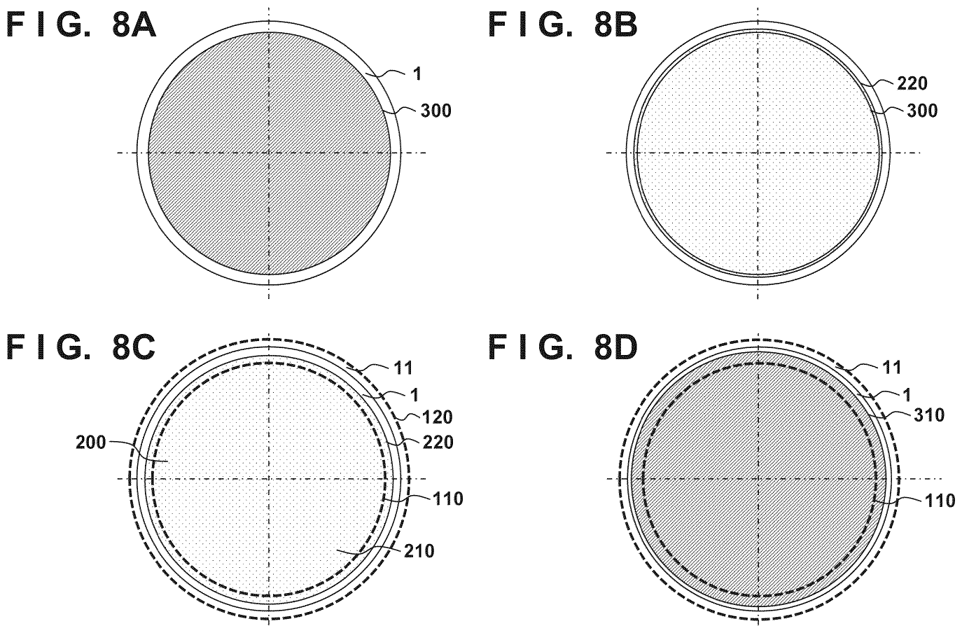

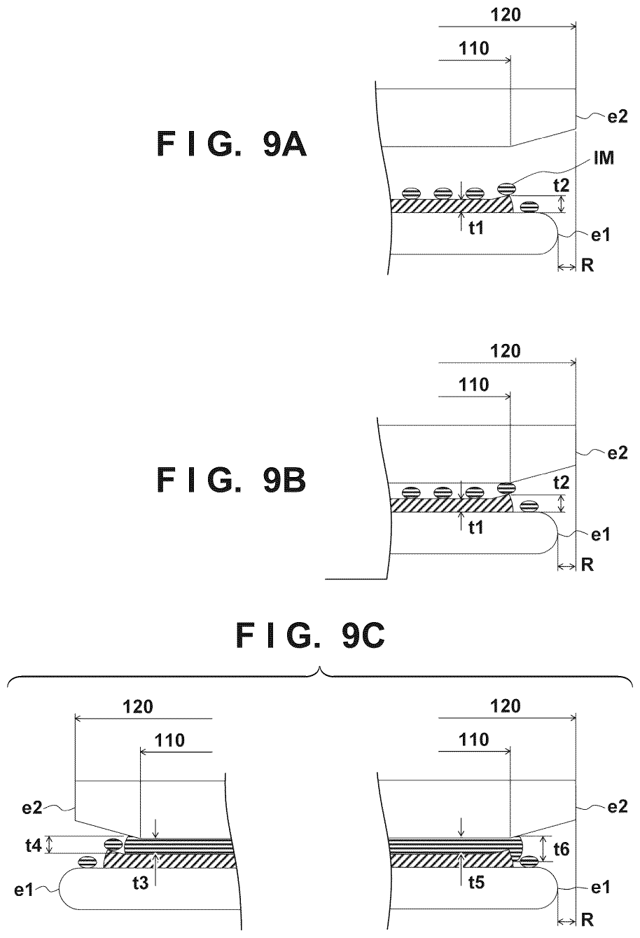

FIG. 8A shows the spread end 300 of the curable material IM formed in the previous planarization process. FIG. 8B shows a state in which the curable material IM is applied to an application range 220 exceeding the spread end 300 of the curable material IM formed in the previous planarization process. In the state shown in FIG. 8B, the curable material IM covers the spread region D2 shown in FIG. 7B and formed in the previous planarization process. In this case, as shown in FIG. 9A, a bulging portion t2 of the outer peripheral portion of the spread region D2 formed by the tapered portion of the mold 11 in the previous planarization process is also covered with the curable material IM. In addition, the curable material IM may be applied to a region outside the spread region D2 formed in the previous planarization process depending on application conditions and application position accuracy. When the curable material IM is applied to a region outside the spread region D2, the curable material IM may adhere to the end face e1 of the substrate 1 or to a region outside the substrate 1. In addition, when the curable material IM is applied to a region outside the spread region D2, the curable material IM protruding from the spread region D2 may not be irradiated with curing light and hence may not be cured. Alternatively, if the curable material IM is a heat-curing material, when the curable material IM is applied to a region outside the spread region D2, heat to be applied does not reach the curable material IM protruding from the spread region D2 and hence may not be cured. However, such phenomena can sometimes be accepted as long as they do not lead to problems such as contamination of the apparatus or the material.

The controller 40 performs positioning of the substrate 1 and the mold 11 based on the result of the measurement of the substrate 1 in step S3. However, due to measurement control errors and the like, the result of the positioning of the substrate 1 and the mold 11 does not perfectly match the result of the previous positioning, and the positioning error R can occur as shown in FIG. 7E. In step S6, the center of the substrate 1 is matched with the center of the mold 11 in the presence of the positioning error R, and the curable material IM is brought into contact with the mold 11. FIG. 7F shows a state in which such contact has occurred. At this time, as shown in FIG. 9B, since the bulging portion t2 of the curable material IM of the outer peripheral tapered portion formed in the previous planarization process is covered with the curable material IM, dry contact between the substrate 1 and the bulging portion t2 is prevented.

Upon contact with the mold 11, the curable material IM spreads up to a spread end 310 as an end portion of the spread region represented by the hatching pattern in FIG. 8D. At this time, the spread end 310 spreads to the outside of the taper start portion 110 of the mold 11. As shown in FIG. 7G, if the mold 11 comes into contact with the substrate 1 with a positional shift, the curable material spreads to the left and right sides differently. On the left side in FIG. 7G, as shown in FIG. 9C, the radial spread of the curable material IM exuding from between the flat portion of the mold 11 and the planarized film formed in the previous planarization process is converted into a spread in a direction in which the film thickness increases from a film thickness t3 to a film thickness t4. This facilitates suppressing the spread of the curable material IM in the radial direction and can prevent the curable material IM from adhering to the end face e1 of the substrate 1 and the end face e2 of the mold 11. On the right side in FIG. 7G, as shown in FIG. 9C, the radial spread of the curable material IM exuding from between the flat portion of the mold 11 and the planarized film formed in the previous planarization process is converted into a spread in a direction in which the film thickness increases from a film thickness t5 to a film thickness t6. This facilitates suppressing the spread of the curable material IM in the radial direction and can prevent the curable material IM from adhering to the end face e1 of the substrate 1 and the end face e2 of the mold 11. In order to obtain such effects, for example, the tapered surface preferably has a taper angle of 0.10 to 20° with respect to the flat surface. In addition, the area of the tapered surface can be 1/15 or less of the area of the flat surface. Furthermore, the length of the tapered surface of the superstrate in the radial direction is preferably at least 0.2 mm.

Note that depending on the application amount of the curable material IM, the curable material IM that has exuded upon contact may not necessarily increase in film thickness. In addition, although the curable material IM that has not come into contact with the mold 11 in a contact step is directly subjected to a curing process, no problem arises unless there are influences on quality, steps, and the like.

According to the embodiment described above, it is possible to prevent dry contact even if a planarization process is executed a plurality of times. It is also possible to prevent the curable material IM from exuding from between the mold 11 and the substrate 1 and adhering to an end portion of the substrate or the mold due to a factor such as a large application amount of the curable material IM or a large application area.

### <Embodiment of Article Manufacturing Method>

A method of manufacturing an article (a semiconductor IC element, a liquid crystal display element, a color filter, a MEMS, or the like) by using the above-described planarization apparatus will be described next. The manufacturing method includes, by using a film forming apparatus as the above-described planarization apparatus, a step of planarizing a composition arranged on a substrate (a wafer, a glass substrate, or the like) and a step of curing the composition. With this, a planarized film is formed on the substrate. Then, processing such as pattern formation using a lithography apparatus is performed on the substrate with the planarized film formed thereon, and the processed substrate is processed in other known processing steps to manufacture an article. Other known steps include patterning exposure and accompanying preprocessing, etching, resist removal, dicing, bonding, packaging, and the like. This manufacturing method can manufacture an article with higher quality than the conventional methods.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-134156, filed Aug. 21, 2023, which is hereby incorporated by reference herein in its entirety.

What is claimed is:

1. A planarization method of repeatedly performing a planarization process a plurality of times on the same surface of a substrate, the planarization process including:
supplying a curable material onto a substrate;
forming a liquid film on the substrate by bringing a superstrate into contact with the curable material supplied onto the substrate;
forming a cured film by curing the liquid film; and
separating the superstrate from the cured film,
wherein the superstrate is provided with a tapered surface connecting a side end face to a flat surface forming a lower surface facing the substrate, and
in the supplying the curable material in a second planarization process after a first planarization process, the curable material is supplied so as to cover a region of the cured film formed under the tapered surface in the first planarization process with a liquid film formed in the forming the liquid film in the second planarization process.

2. The method according to claim 1, wherein a supply range of the curable material in the supplying the curable material in the second planarization process is wider than the cured film formed in the first planarization process.

3. The method according to claim 1, wherein a supply range of the curable material in the supplying the curable material in the second planarization process is inside an outer peripheral end of the cured film formed in the first planarization process, and the liquid film spreads over the outer peripheral end of the cured film in the forming the liquid film in the second planarization process.

4. The method according to claim 1, wherein a supply range of the curable material in the supplying the curable material in the second planarization process is −0.5 mm larger than an outer peripheral end of the cured film formed in the first planarization process.

5. The method according to claim 1, wherein the second planarization process includes
measuring an outer peripheral end of the cured film formed in the first planarization process, and
deciding a supply range and supply amount of the curable material in the supplying the curable material in the second planarization process based on the measured outer peripheral end.

6. The method according to claim 1, further comprising positioning the substrate and the superstrate before or during the forming the liquid film.

7. The method according to claim 1, wherein the superstrate has a diameter of 200 mm to 400 mm.

8. The method according to claim 7, wherein the tapered surface has a taper angle of 0.1° to 20° with respect to the flat surface.

9. The method according to claim 8, wherein the area of the tapered surface is not more than 1/15 of an area of the flat surface.

10. The method according to claim 9, wherein the tapered surface of the superstrate in a radial direction has a length of at least 0.2 mm.

11. A method of manufacturing an article, the method comprising:
forming a film of a curable material on a substrate according to a planarization method defined in claim 1; and
processing the substrate on which the film is formed in the forming,
wherein the article is manufactured from the processed substrate.
